(19) United States
(12) Patent Application Publication
(10) Pub. No.: US 2019/0012259 A1
(43) Pub. Date: Jan. 10, 2019

(54) LBA EVICTION IN PCM MEDIA

(71) Applicant: Futurewei Technologies, Inc., Plano, TX (US)

(72) Inventors: Xiangyu Tang, San Jose, CA (US); Xiaobing Lee, Santa Clara, CA (US); Yunxiang Wu, Cupertino, CA (US); Ken Hu, San Jose, CA (US)

(21) Appl. No.: 15/643,404

(22) Filed: Jul. 6, 2017

(51) Int. Cl. G06F 12/02; G06F 12/0868

(52) U.S. Cl. CPC G06F 12/0238; G11C 13/0004; G06F 12/0868

(57) ABSTRACT

According to various aspects of the present disclosure, there is provided a method and an apparatus for writing and evicting data in a phase-change memory (PCM). In one embodiment, a logical block address (LBA) eviction candidate (LEC) list is stored in the PCM media. The LEC list employs a circular queue having a head end and tail end, where new LBAs are inserted at the head end. In one embodiment, a tail end LBA at the tail end of the LEC list along with all the subsequent LBAs on the LEC list with continuing write sequence number to that of the tail end LBA are evicted when data needs to be evicted from the PCM media.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

Phase-change memory (PCM) is a form of computer random-access memory (RAM) that stores data by altering the state of the matter from which the device is fabricated. The structure of the material can change rapidly back and forth between amorphous and crystalline on a microscopic scale. In the amorphous or disordered phase, the material has high electrical resistance; in the crystalline or ordered phase, its resistance is reduced. This allows electrical currents to be switched on and off, representing digital high and low states.

PCM technology has the potential to provide inexpensive, high-speed, high-density, high-volume nonvolatile storage. For instance, PCM is sometimes called “perfect RAM” (PRAM) because data can be overwritten without having to erase it first. This makes it possible for PCM to function many times faster than conventional flash memory while using less power. In addition, PCM chips are expected to last several times as long as currently available flash memory chips and may prove cheaper to mass-produce.

### SUMMARY

According to one aspect of the present disclosure, there is provided a method and an apparatus for writing and evicting data in a PCM media. In one embodiment, a logical block addressing (LBA) Eviction Candidate (LEC) list is stored in the PCM media. The LEC list employs a circular queue having a head end and a tail end. In one embodiment, new LBAs are inserted at the head end. A tail end LBA at the tail end of the LEC list is evicted in response to a determination that data needs to be evicted from the PCM media. When this occurs, a determination is made as to whether there are subsequent LBAs on the LEC list with continuing write sequence number to that of the tail end LBA. If there are subsequent LBAs on the LEC list with continuing write sequence number to that of the tail end LBA, all the subsequent LBAs on the LEC list with continuing write sequence number to that of the tail end LBA are evicted along with the tail end LBA.

Optionally, in any of the preceding aspects the head end and the tail end of the eviction list may be cached in static random access memory (SRAM) for quick access.

Optionally, in any of the preceding aspects when an LBA is written by the host to the PCM media, a determination is made as to whether the LBA is tagged in an eviction category. If the LBA is tagged in an eviction category, a determination is made as to whether the LBA exists in the LEC list. If the LBA is not in the LEC list, the LBA is inserted into the head end of the LEC list. In one embodiment, if the LBA already exists in the LEC list, a hot flag for the LBA is set to indicate that the LBA has been written to the PCM media during a cycle of the LEC list. In this embodiment, when data needs to be evicted from the PCM media, prior to evicting the tail end LBA, a hot flag determination is performed to determine whether the tail end LBA has the hot flag set. If the tail end LBA has the hot flag set, the tail end LBA is moved to the head end of the LEC list and the hot flag is reset. Additionally, in one embodiment, if there are subsequent LBAs on the LEC list at the tail end with continuing write sequence number to that of the tail end LBA, all the subsequent LBAs on the LEC list with continuing write sequence number to that of the tail end LBA are moved along with the tail end LBA to the head end of the LEC list. The process then repeats the hot flag determination on a new tail end LBA at the tail end of the LEC list. In one embodiment, if the tail end LBA does not have the hot flag set, the tail end LBA and all the subsequent LBAs on the LEC list with continuing write sequence number to that of the tail end LBA are evicted. In one embodiment, setting the hot flag involves incrementing a counter value by one for each time the LBA is written to the PCM media, and resetting the hot flag involves decrementing the counter value by one. In this embodiment, the hot flag is considered to be set if the counter value is greater than an initial value of the counter value (e.g., if the initial value of the counter value for the hot flag is 0, then the hot flag is considered to be set if the counter value is greater than 0). In one embodiment, the counter value has a predetermined max value, wherein additional writes of the LBA does not increase the counter value beyond the max value.

Optionally, in any of the preceding aspects the LEC list may be stored in the PCM media using small memory units (SMUs). Additionally, the LEC list may be organized into segments. In one embodiment, each segment may be stored in an SMU. In one embodiment, the segment may include 14 entries and is 50 bytes long. In one embodiment, each entry in the segment is 28 bits comprising a 27 bit LBA and one reserve bit.

Other features of the various embodiments and advantages thereof are described below in the Detailed Description.

### BRIEF DESCRIPTION OF THE DRAWINGS

For a more complete understanding of this disclosure, reference is now made to the following brief description, taken in connection with the accompanying drawings and detailed description, wherein like reference numerals represent like parts;

FIG. 1 is a schematic diagram illustrating an LEC List according to a first embodiment of the disclosure;

FIG. 2 is a flow diagram illustrating a method for inserting LBA in the LEC list in accordance with the first embodiment of FIG. 1;

FIG. 3 is a flow diagram illustrating a method for evicting LBA from the LEC list in accordance with the first embodiment of FIG. 1;

FIG. 4 is a schematic diagram illustrating an LEC List in accordance with a second embodiment;

FIG. 5 is a flow diagram illustrating a method for inserting LBA in the LEC list in accordance with the second embodiment of FIG. 4;

FIG. 6 is a flow diagram illustrating a method for evicting LBA from the LEC list in accordance with the second embodiment of FIG. 4;

FIG. 7 is a schematic diagram illustrating an LEC list segment in accordance with an embodiment;

FIG. 8 is a schematic diagram illustrating an LEC list entry format in accordance with an embodiment; and

FIG. 9 is a schematic diagram illustrating a network device in accordance with an embodiment of the disclosure.

### DETAILED DESCRIPTION

It should be understood at the outset that although illustrative implementations of one or more embodiments are provided below, the disclosed systems and/or methods may be implemented using any number of techniques, whether currently known or in existence. The disclosure should in no way be limited to the illustrative implementations, drawings, and techniques illustrated below, including the exemplary designs and implementations illustrated and described herein, but may be modified within the scope of the appended claims along with their full scope of equivalents.

The disclosed embodiments seek to improve the process of evicting cold data in PCM in order to make room for new host writes into PCM. The disclosed embodiments may be applied to various types of PCM media including but not limited to 3D XPoint PCM or X3D developed by Intel® and Micron Technology®. The disclosed embodiments may also be applicable to any type of media that is used as a cache. For example, in one embodiment, PCM media may be used as a cache for frequently accessed data. For instance, in one embodiment, a hybrid storage may pair PCM media with NAND flash in which frequently accessed data is stored in the PCM media.

Technical advantages of the disclosed embodiments include providing a more efficient and accurate method for identifying less frequently accessed data and evicting them from the PCM media. For example, one aspect of the disclosed embodiments takes advantage of the fact that a host file system provides hints on the data temperature (i.e., how often the data is accessed).

Another aspect or advantage of the disclosed embodiments eliminates the need to search for an eviction candidate in a logical-to-physical (L2P) mapping table. For instance, in current PCM/NAND hybrid storage configuration, only about 3 percent of L2P entries store LBAs written to the PCM, thus the length of the search to find the acceptable LBA is not deterministic and could be long. LBA is a common scheme used for specifying the location of blocks of data stored on computer storage devices. In essence, LBA is a means by which a storage media is accessed by linearly addressing sector addresses, beginning at sector 1 of head 0, cylinder 0 as LBA 0, and proceeding on in sequence to the last physical sector on the storage media.

Still another advantage of the disclosed embodiments is that it evicts LBAs in similar order to the order in which they are written by the host. This way, large sequential writes are preserved when evicting to NAND or other data storage mediums. According to one aspect of the present disclosure, the above improvements are obtained by maintaining an LEC list.

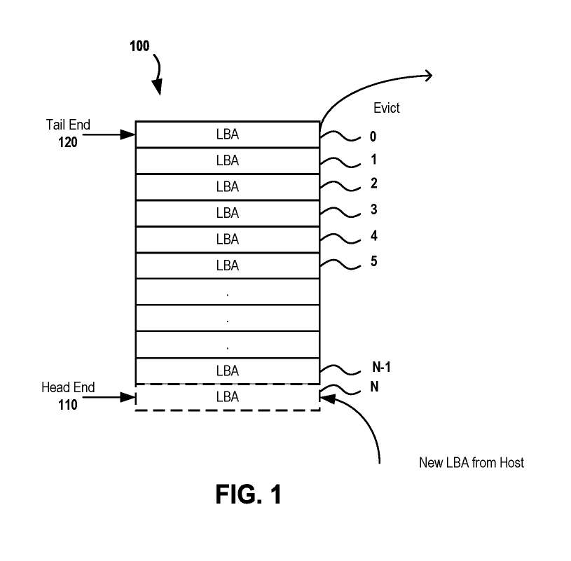

FIG. 1 is a schematic diagram illustrating an LEC list 100 according to a first embodiment of the disclosure. In the depicted embodiment, the LEC list 100 includes LBA 0, LBA 1, LBA 2, LBA 3, LBA 4, LBA 5, [ . . . ], LBA N−1, and LBA N. The variable N is a numeral representing the last number in the LBA sequence that is inserted into the LEC list 100. The LEC list 100 employs a circular queue having a head end 110 and a tail end 120. New LBAs written by the host system are inserted at the head end 110 and are moved sequentially towards the tail end 120. LBAs are evicted from the tail end 120.

In one embodiment, the LEC list 100 is stored on the PCM media of a host system. In one embodiment, the LEC list 100 may be stored in the PCM media using SMUs. In some embodiments, the head end 110 and the tail end 120 of the LEC list 100 may be cached in SRAM for quick access. In one embodiment, the maximum number of entries in the LEC list 100 is equal to the maximum number of LBAs stored in the PCM media.

In one embodiment, not every LBA that is written by the host is inserted into the LEC list 100. As an example, the disclosed embodiments may utilize data provided by a host system to determine which LBAs are inserted into the LEC list 100 and considered for eviction. For instance, in a Flash-Friendly File System (F2FS), each LBA accessed by the host system is given a temperature tag: metadata, hot inode, hot data, warm inode, warm data, cold inode, cold data. In one embodiment, only LBAs with the warm data tag or cold data tag are considered for eviction. The particular data or criteria that are used for determining which LBAs are placed in the LEC list 100 and considered for eviction are referred to herein as an eviction tag. For example, in another embodiment, the eviction tag may be set to only LBAs with the cold data tag. Still, in another embodiment, only LBAs with the warm data tag are inserted into the LEC list 100 and considered for eviction. For example, in one embodiment, LBAs with the cold data tag may be automatically written to NAND and only LBAs with the warm data tag are cached in the PCM media and considered for eviction using the LEC list 100. Other embodiments may utilize other hints or combination of hints provided by the host system as the eviction tag. By utilizing the hints provided by the host system, the disclosed embodiments provide a more efficient method of determining which LBAs to evict.

In accordance with the disclosed embodiments, as the host system writes an LBA that has the designated eviction tag to the PCM media, the LBA is inserted into the LEC list 100 at the head end 110 if the LBA is not already in the LEC list 100. If for some reason eviction is required, such as when a write cache has reached its designed limit, the LBA at the tail end 120 of the LEC list 100 is evicted. In one embodiment, to ensure that sequentially is maintained, all subsequent LBAs on the LEC list 100 with continuing write sequence number to the evicted LBA are also evicted. As referenced herein, a continuing write sequence number is a sequence of either one or more numeric, alphanumeric or purely alphabetical characters that indicate that the LBA is part of the same file as the preceding LBA in the LEC list 100. For example, in one embodiment, if the LBA and the preceding LBA have a write sequence number that share the same file name and only differ by a sequence of numbers at the end of the filename, then the LBA is determined to have a continuing write sequence number to the preceding LBA in the LEC list 100. By performing this additional process, the disclosed embodiments assist in preventing the data and/or the PCM media from becoming fragmented, which may reduce capacity or efficiency of the PCM media.

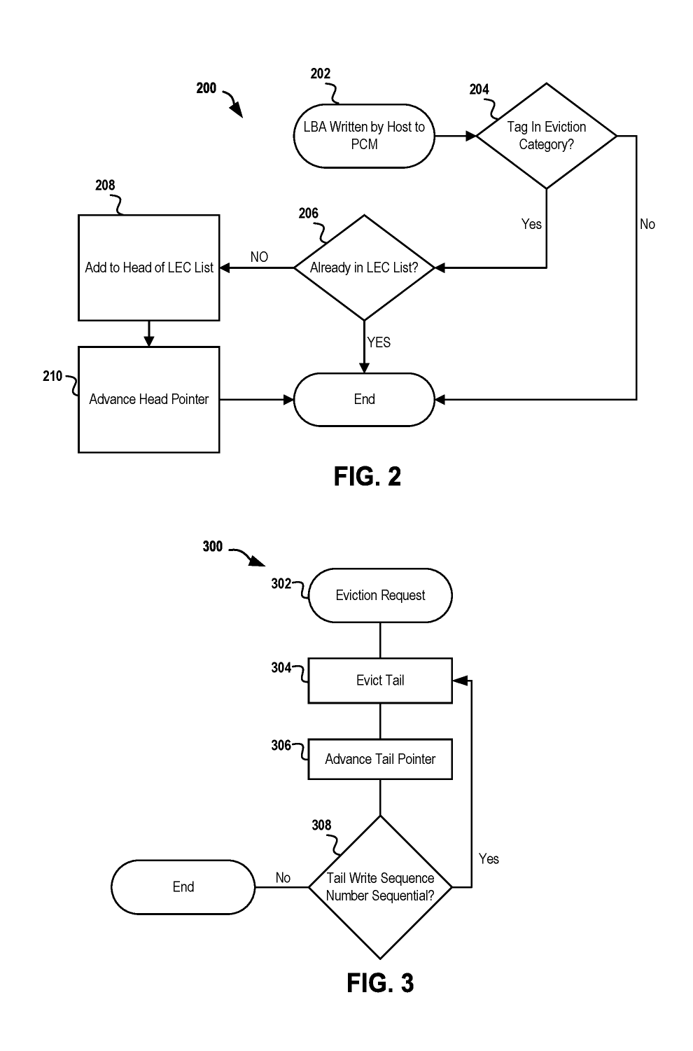

FIG. 2 is a flow diagram illustrating a method 200 for inserting an LBA into the LEC list 100 in accordance with an embodiment. The method 200 begins at step 202 by the host system writing an LBA to the PCM media. At step 204, the method 200 determines if the LBA has a tag that is in the eviction category. For example, as stated above, in one embodiment, only LBAs with a warm data tag or a cold data tag are considered for eviction. If the method 200 determines that the LBA does not have a tag in the eviction category, the method 200 does not insert the LBA into the LEC list 100 and terminates.

If the method 200 determines that the LBA does have a tag in the eviction category, the method 200 determines if the LBA already exists in the LEC list 100 at step 206. If the method 200 determines at step 206 that the LBA already exists in the LEC list 100, in this embodiment, the method 200 does not perform any additional steps and terminates.

However, if the method 200 at step 206 determines that the LBA does not exist in the LEC list 100, the method 200 at step 208 inserts the LBA into the LEC list 100 at the head end 110. The method 200 at step 210 moves all other LBAs in the LEC list 100 (if any are present) sequentially towards the tail end 120 of the LEC list 100 by advancing a head pointer to the newly inserted LBA at the head end 110 of the LEC list 100. The head pointer refers to (or “points to”) a location in the PCM media using its memory address. The value stored at that location is obtained by dereferencing the pointer. The method 200 then terminates.

FIG. 3 is a flow diagram illustrating a method 300 for evicting an LBA from the LEC list 100 in accordance with the first embodiment of FIG. 1. The method 300 begins by receiving an eviction request to evict data from the PCM media at step 302. At step 304, the method 300 evicts the LBA at the tail end 120 of the LEC list 100.

At step 306, the method 300 advances the tail pointer of the LEC list 100 to the next LBA in the LEC list 100, thereby making it the tail end 120 of the LEC list 100. At step 308, the method 300 determines if the new LBA at the tail end 120 of the LEC list 100 has a continuing write sequence number to the evicted LBA. If the method 300 determines that the new LBA at the tail end 120 of the LEC list 100 does not have a continuing write sequence number to the evicted LBA, the method 300 terminates.

However, if the method 300 determines that the new LBA at the tail end 120 of the LEC list 100 does have a continuing write sequence number to the evicted LBA, the method 300 repeats at step 304 and evicts the LBA at the tail end 120 of the LEC list 100. The method 300 then advances the tail pointer of the LEC list 100 to the next LBA in the LEC list 100, thereby making it the tail end 120 of the LEC list 100, and repeats the continuing write sequence number determination at step 308 on the new LBA at the tail end 120 of the LEC list 100.

If the method 300 determines that the new LBA at the tail end 120 of the LEC list 100 does not have a continuing write sequence number to the evicted LBA, the method 300 terminates.

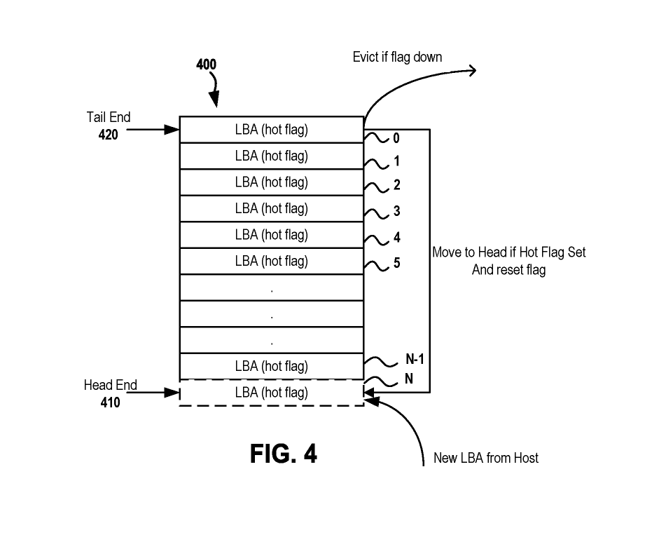

FIG. 4 is a schematic diagram illustrating an LEC list 400 in accordance with a second embodiment. Similar to the LEC list 100, the LEC list 400 includes the LBA 0, LBA 1, LBA 2, LBA 3, LBA 4, LBA 5, [ . . . ], LBA N−1, and LBA N. As the host system writes an LBA that has the designated eviction tag to the PCM media, the LBA is inserted into the LEC list 400 at the head end 410 if the LBA is not already in the LEC list 400. If eviction is required, the LBA at the tail end 420 of the LEC list 400 is evicted.

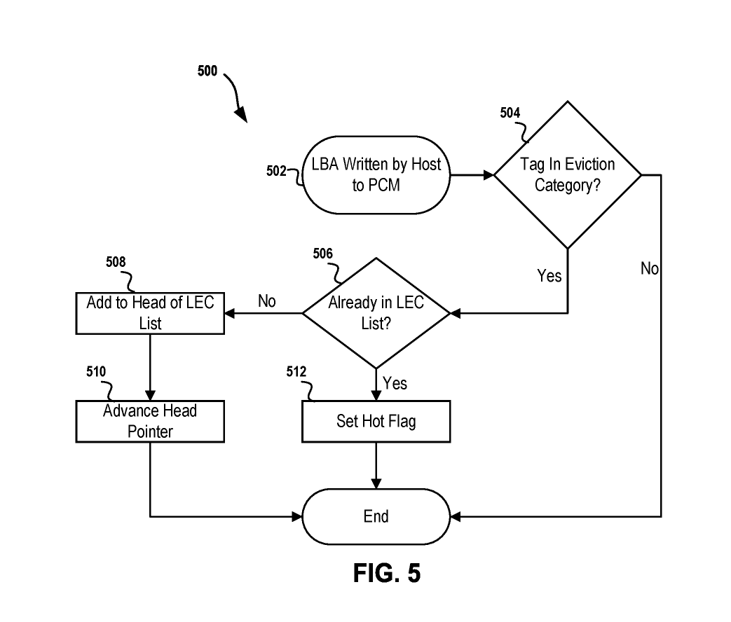

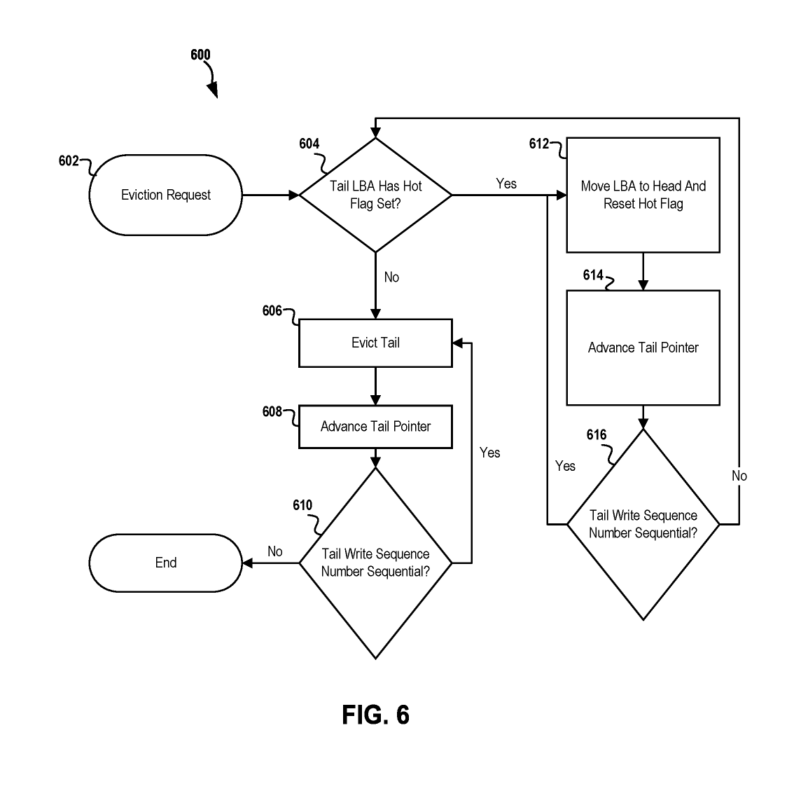

The difference between the LEC list 100 and the LEC list 400 is that each of the LBAs in the LEC list 400 includes a hot flag option or value that may be set to indicate how often a particular LBA is written by the host to the PCM media. This process is further described in FIG. 5. Additionally, in this embodiment, based on whether the hot flag option or value is set for a particular LBA at the tail end 420 of the LEC list 400 will determine whether the LBA is evicted from the PCM media or moved to the head end 410 of the LEC list 400. This process is further described in FIG. 6.

FIG. 5 is a flow diagram illustrating a method 500 for inserting an LBA into the LEC list 400 in accordance with an embodiment. The method 500 begins at step 502 by the host system writing an LBA to the PCM media. At step 504, the method 500 determines if the LBA has a tag that is in the eviction category. For example, as stated above, in one embodiment, only LBAs with a warm data tag or a cold data tag are considered for eviction. If the method 500 determines that the LBA does not have a tag in the eviction category, the method 500 does not insert the LBA into the LEC list 400 and terminates.

If the method 500 determines that the LBA does have a tag in the eviction category, the method 500 determines if the LBA already exists in the LEC list 400 at step 506. If the method 500 determines at step 506 that the LBA does not exist in the LEC list 400, the method 500 at step 508 inserts that LBA into the LEC list 400 at the head end 410. The method 500 at step 510 moves the other LBAs in the LEC list 400 (if any are present) sequentially towards the tail end 420 of the LEC list 400 by advancing a head pointer to the newly inserted LBA at the head end 410 of the LEC list 400. The method 500 then terminates.

However, if the method 500 determines at step 506 that the LBA already exists in the LEC list 400, in this embodiment, the method 500 at step 512 sets the hot flag for the LBA to indicate that the LBA has been written to the PCM media during a cycle of the LEC list 400 and then the method 500 terminates. In one embodiment, setting the hot flag involves incrementing a counter value by one for each time the LBA is written to the PCM media during a cycle of the LEC list 400. In another embodiment, the counter value may only be incremented once per cycle of the LEC list 400 irrespective of how many times an LBA is written to the PCM media during a cycle of the LEC list 400. In one embodiment, the counter value has a predetermined max value, wherein additional writes of the LBA do not increase the counter value beyond the max value. In these embodiments, the hot flag is considered to be set if the counter value is greater than an initial value of the counter value. For example, in one embodiment, if the initial value of the counter value for the hot flag is 0, then the hot flag is considered to be set if the counter value is greater than 0. Alternatively, in another embodiment, the counter value or hot flag may be binary such as 0 or FALSE to indicate that the hot flag is not set, and 1 or TRUE to indicate that the hot flag is set. As described below in FIG. 6, the hot flag is used in determining if an LBA at the tail end 420 of the LEC list 400 should be evicted when an eviction is required.

FIG. 6 is a flow diagram illustrating a method 600 for evicting an LBA from the LEC list 400 in accordance with an embodiment. The method 600 begins by receiving an eviction request to evict data from the PCM media at step 602. At step 604, the method 600 determines if the LBA at the tail end 420 of the LEC list 400 has its hot flag set. As stated above, in one embodiment, the hot flag is considered set if it set to TRUE or is a value greater than an initial starting value, such as 1, 2, or 3, when the initial starting value is 0. In this embodiment, if the method 600 determines at step 604 that the hot flag is set for the LBA at the tail end 420 of the LEC list 400, the method 600 at step 612 moves the LBA at the tail end 420 to the head end 410 of the LEC list 400 and resets the hot flag for the LBA. In one embodiment, resetting the hot flag involves decrementing the counter value by one. As stated above, in this embodiment, the hot flag may still be considered to be set even after decrementing the counter value by one if the counter value is still greater than an initial starting value. Alternatively, in another embodiment, the hot flag may be set back to FALSE to indicate that it has been reset.

At step 614, the method 600 advances the tail pointer of the LEC list 400 to the next LBA in the LEC list 400, thereby making it the tail end 420 of the LEC list 400. At step 616, the method 600 determines if the new LBA at the tail end 420 of the LEC list 400 has a continuing write sequence number to the evicted LBA. If the method 600 determines that the new LBA at the tail end 420 of the LEC list 400 does have a continuing write sequence number to the evicted LBA, the method 600 repeats at step 612 and moves the new LBA at the tail end 420 of the LEC list 400 to the head end 410 of the LEC list 400. If the method 600 determines that the new LBA at the tail end 420 of the LEC list 400 does not have a continuing write sequence number to the evicted LBA, the method 600 repeats at the process at step 604 by determining if the new LBA at the 420 of the LEC list 400 has its hot flag set.

If the method 600 determines at step 604 that the hot flag is not set for the LBA at the tail end 420 of the LEC list 400, the method 600 at step 606 evicts the LBA at the tail end 420 of the LEC list 400. At step 608, the method 600 advances the tail pointer of the LEC list 400 to the next LBA in the LEC list 400, thereby making it the tail end 420 of the LEC list 400. At step 610, the method 600 determines if the new LBA at the tail end 420 of the LEC list 400 has a continuing write sequence number to the evicted LBA. If the method 600 determines that the new LBA at the tail end 420 of the LEC list 400 does not have a continuing write sequence number to the evicted LBA, the method 600 terminates.

However, if the method 600 determines that the new LBA at the tail end 420 of the LEC list 400 does have a continuing write sequence numbers to the evicted LBA, the method 600 repeats at step 606 and evicts the LBA at the tail end 420 of the LEC list 400. The method 600 then advances the tail pointer of the LEC list 400 to the next LBA in the LEC list 400 at step 608, thereby making it the tail end 420 of the LEC list 400 and repeats the continuing write sequence number determination at step 610 on the new LBA at the tail end 420 of the LEC list 400. If the method 600 determines that the new LBA at the tail end 420 of the LEC list 400 does not have a continuing write sequence number to the evicted LBA, the method 600 terminates.

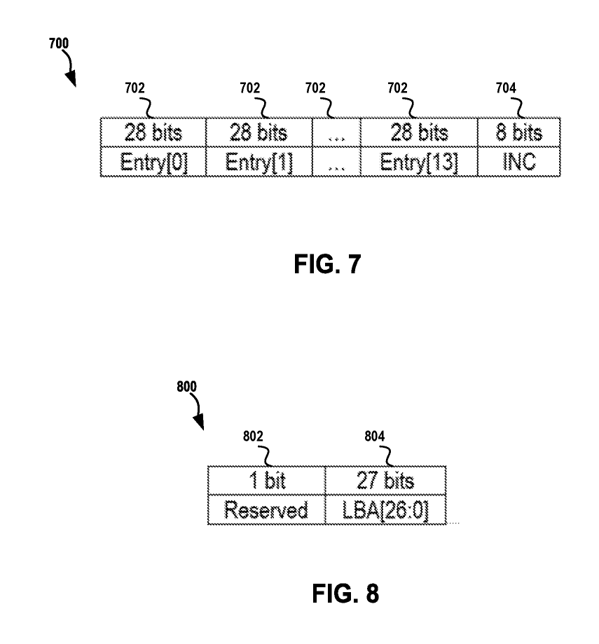

FIG. 7 is a schematic diagram illustrating an LEC list segment 700 in accordance with an embodiment. As stated above, in one embodiment, the LEC list 100 or LEC list 400 may be stored in the PCM media using SMU that are protected by error-correcting codes, cyclic redundancy checks (CRCs) and/or other codes designed to protect against random errors and degradation in media health. In one embodiment, the LEC list 100 or LEC list 400 are organized into segments such as, but not limited to, the LEC list segment 700. In one embodiment, the segments may be stored in random order anywhere in the PCM media. In one embodiment, the LEC list segment 700 is made up of 400 bits or 50 bytes and is stored in an SMU. In one embodiment, the LEC list segment 700 includes fourteen LEC list entries 702 and an increment (INC) field 704. In one embodiment, the LEC list entries 702 are each 28 bits and the INC field 704 is 8 bits (or 1 byte).

In one embodiment, each segment contains an address linking to the next ordered segment in the list. For example, in one embodiment, the INC field 704 is used to indicate the value to be added to the segment index to discover the next segment in the list. For instance, in one embodiment, if all SMUs are good, the INC field 704 is set to 1 in all segments. If however there is a particular SMU that is bad (e.g., an SMU may be corrupted), the INC field 704 in the segment preceding the bad SMU may be set to 2 (or more if multiple SMUs are bad). In this embodiment, because the INC field 704 is one byte, the disclosed embodiment supports up to 126 consecutive bad SMUs.

FIG. 8 is a schematic diagram illustrating an LEC list entry format 800 in accordance with an embodiment. As stated above, in one embodiment, the LEC list entry format 800 consists of 28 bits that includes a 27-bit long LBA 804 and a spare bit 802. In one embodiment, the spare bit 802 may be reserved for future use.

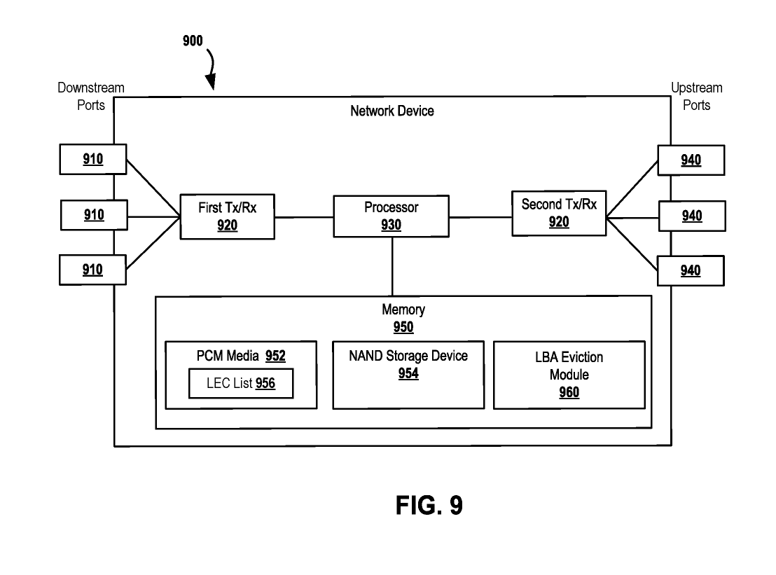

FIG. 9 is a schematic diagram illustrating an example of a network device 900 that may be deployed in accordance with an embodiment of the disclosure. The network device 900 comprises one or more downstream ports 910 coupled to a first transceiver (Tx/Rx) 920, which comprise transmitters, receivers, or combinations thereof. The first Tx/Rx 920 transmits and/or receives frames from other network nodes via the downstream ports 910. Similarly, the network device 900 comprises a second Tx/Rx 920 coupled to a plurality of upstream ports 940, wherein the second Tx/Rx 920 transmits and/or receives frames from other nodes via the upstream ports 940. The downstream ports 910 and/or the upstream ports 940 include electrical and/or optical transmitting and/or receiving components. In another embodiment, the network device 900 comprises one or more antennas (not shown) coupled to the first and second Tx/Rx 920. The first and second Tx/Rx 920 transmits and/or receives data (e.g., packets) from other network elements via wired or wireless connections, depending on the embodiment.

A processor 930 is coupled to the first and second Tx/Rx 920 and is configured to process the incoming data and/or determine to which nodes to send (e.g., transmit) the data. In an embodiment, the processor 930 comprises one or more multi-core processors (not shown) and/or memory modules 950, which function as data stores, buffers, etc. The processor 930 is implemented as a general processor or as part of one or more application specific integrated circuits (ASICs), field-programmable gate arrays (FPGAs), and/or digital signal processors (DSPs). Although illustrated as a single processor, the processor 930 is not so limited and may comprise multiple processors. The processor 930 is configured to communicate and/or process multi-destination frames.

FIG. 9 illustrates that a memory module 950 is coupled to the processor 930 and is a non-transitory medium configured to store various types of data and/or instructions. Memory module 950 comprises memory devices including secondary storage, read-only memory (ROM), and random-access memory (RAM). The secondary storage is typically comprised of one or more disk drives, optical drives, solid-state drives (SSDs), and/or tape drives and is used for non-volatile storage of data and as an over-flow storage device if the RAM is not large enough to hold all working data. The secondary storage is used to store programs which are loaded into the RAM when such programs are selected for execution. The ROM is used to store instructions and perhaps data that are read during program execution. The ROM is a non-volatile memory device which typically has a small memory capacity relative to the larger memory capacity of the secondary storage. The RAM is used to store volatile data and perhaps to store instructions. Access to both the ROM and RAM is typically faster than to the secondary storage.

As described above, in one embodiment, the memory module 950 may comprise a hybrid storage system that includes PCM media 952 and a NAND storage device 954. As stated above, in one embodiment, an LEC list 956 such as LEC list 100 or LEC list 400 is stored in the PCM media 952. The memory module 950 further stores the instructions for carrying out the various embodiments described herein. For example, in one embodiment, the memory module 950 comprises an LBA eviction module 960 comprising instructions and other data that when executed by the processor 930 performs the processes described herein for writing and evicting data in a PCM media. In one embodiment, the LBA eviction module 960 may be stored in the PCM media 952 and/or the NAND storage device 954.

It is understood that by programming and/or loading executable instructions onto the network device 900, at least one of the processors 930 and the memory module 950 are changed, transforming the network device 900 in part into a particular machine or apparatus having the novel functionality taught by the present disclosure. It is fundamental to the electrical engineering and software engineering arts that functionality that can be implemented by loading executable software into a computer can be converted to a hardware implementation by well-known design rules known in the art. Decisions between implementing a concept in software versus hardware typically hinge on considerations of stability of the design and number of units to be produced rather than any issues involved in translating from the software domain to the hardware domain. Generally, a design that is still subject to frequent change may be preferred to be implemented in software, because re-spinning a hardware implementation is more expensive than re-spinning a software design. Generally, a design that is stable and will be produced in large volume may be preferred to be implemented in hardware (e.g., in an ASIC) because for large production runs the hardware implementation may be less expensive than software implementations. Often a design may be developed and tested in a software form and then later transformed, by well-known design rules known in the art, to an equivalent hardware implementation in an ASIC that hardwires the instructions of the software. In the same manner as a machine controlled by a new ASIC is a particular machine or apparatus, likewise a computer that has been programmed and/or loaded with executable instructions may be viewed as a particular machine or apparatus.

Any processing of the present disclosure may be implemented by causing a processor (e.g., a general purpose multi-core processor) to execute a computer program. In this case, a computer program product can be provided to a computer or a network device using any type of non-transitory computer readable media. The computer program product may be stored in a non-transitory computer readable medium in the computer or the network device. Non-transitory computer readable media include any type of tangible storage media. Examples of non-transitory computer readable media include magnetic storage media (such as floppy disks, magnetic tapes, hard disk drives, etc.), optical magnetic storage media (e.g., magneto-optical disks), compact disc read-only memory (CD-ROM), compact disc recordable (CD-R), compact disc rewritable (CD-R/W), digital versatile disc (DVD), Blu-ray (registered trademark) disc (BD), and semiconductor memories (such as mask ROM, programmable ROM (PROM), erasable PROM, flash ROM, and RAM). The computer program product may also be provided to a computer or a network device using any type of transitory computer readable media. Examples of transitory computer readable media include electric signals, optical signals, and electromagnetic waves. Transitory computer readable media can provide the program to a computer via a wired communication line (e.g., electric wires, and optical fibers) or a wireless communication line.

Although FIG. 9 depicts a particular hardware embodiment for implementing the features described herein, it should be understood that the disclosed embodiments are not limited to any particular hardware architecture and may be implemented in devices having varying hardware architecture or components.

Other aspects and embodiments may be understood from the following examples:

### Example 1

A method for writing and evicting data in a phase-change memory (PCM) media, the method comprising:
storing a logical block address (LBA) eviction candidate (LEC) list in the PCM media, wherein the LEC list employs a circular queue having a head end and a tail end, wherein new LBAs are inserted at the head end;
responsive to a determination that data needs to be evicted from the PCM media, evicting a tail end LBA at the tail end of the LEC list;
determining if there are subsequent LBAs on the LEC list with continuing write sequence number to that of the tail end LBA; and
responsive to a determination that there are subsequent LBAs on the LEC list with continuing write sequence number to that of the tail end LBA, evicting all the subsequent LBAs on the LEC list with continuing write sequence number to that of the tail end LBA along with the tail end LBA.

### Example 2

The method of Example 1, wherein the head end and the tail end of the eviction list is cached in static random access memory (SRAM) for quick access.

### Example 3

The method of any one of Examples 1-2, further comprising:
writing an LBA to the PCM media;
determining whether the LBA is tagged in an eviction category;
responsive to a determination that the LBA is tagged in the eviction category, determining whether the LBA exists in the LEC list; and
responsive to a determination that the LBA does not exist in the LEC list, inserting the LBA into the head end of the LEC list.

### Example 4

The method of any one of Examples 1-3, further comprising responsive to a determination that the LBA exists in the LEC list, setting a hot flag for the LBA to indicate that the LBA has been written to the PCM media during a cycle of the LEC list.

### Example 5

The method of any one of Examples 1-4, further comprising:
responsive to the determination that data needs to be evicted from the PCM media, prior to evicting the tail end LBA, performing a hot flag determination to determine whether the tail end LBA has the hot flag set;
responsive to the determination that the tail end LBA has the hot flag set, moving the tail end LBA that has the hot flag set to the head end of the LEC list and resetting the hot flag;
determining if there are subsequent LBAs on the LEC list at the tail end with continuing write sequence number to that of the tail end LBA;
responsive to a determination that there are subsequent LBAs on the LEC list with continuing write sequence number to that of the tail end LBA, moving all the subsequent LBAs on the LEC list with continuing write sequence number to that of the tail end LBA along with the tail end LBA to the head end of the LEC list, and repeating the hot flag determination on a new LBA at the tail end of the LEC list; and
responsive to the determination that the tail end LBA does not have the hot flag set, evicting the tail end LBA and all the subsequent LBAs on the LEC list with continuing write sequence number to that of the tail end LBA.

### Example 6

The method of any one of Examples 1-5, wherein setting the hot flag comprises incrementing a counter value by one for each time the LBA is written to the PCM media, and wherein resetting the hot flag comprises decrementing the counter value by one, and wherein the hot flag is determined to be set if the counter value is greater than an initial value of the counter value.

### Example 7

The method of any one of Examples 1-6, wherein the counter value has a predetermined max value, wherein additional writes of the LBA do not increase the counter value beyond the max value.

### Example 8

The method of any one of Examples 1-7, wherein the LEC list is stored in the PCM media using small memory units (SMUs) that are protected by error-correcting codes designed to protect against random errors, and wherein the LEC list is organized into segments, each segment stored in an SMU.

### Example 9

The method of any one of Examples 1-8, wherein the segments may be stored in random order anywhere in the PCM media.

### Example 10

The method of any one of Examples 1-9, wherein the segment contains an address linking to the next ordered segment in the list.

### Example 11

The method of any one of Examples 1-10, wherein the segment comprises 14 entries and is 50 bytes long, wherein each entry is 28 bits.

### Example 12

The method of any one of Examples 1-11, wherein each entry comprises a 27 bit LBA and one reserve bit.

### Example 13

An apparatus comprising:
a memory for storing executable instructions; and
a processor configured to execute the executable instructions to:
   store a logical block address (LBA) eviction candidate (LEC) list in the phase-change memory (PCM) media, wherein the LEC list employs a circular queue having a head end and a tail end, wherein new LBAs are inserted at the head end;
   responsive to a determination that data needs to be evicted from the PCM media, evict a tail end LBA at the tail end of the LEC list;
   determine if there are subsequent LBAs on the LEC list with continuing write sequence number to that of the tail end LBA; and
   responsive to a determination that there are subsequent LBAs on the LEC list with continuing write sequence number to that of the tail end LBA, evict all the subsequent LBAs on the LEC list with continuing write sequence number to that of the tail end LBA along with the tail end LBA.

### Example 14

The apparatus of Example 13, wherein the processor is configured to further execute the executable instructions to media the head end and the tail end of the eviction list in static random access memory (SRAM) for quick access.

### Example 15

The apparatus of any one of Examples 13-14, wherein the processor is configured to further execute the executable instructions to:
write an LBA to the PCM media;
determine whether the LBA is tagged in an eviction category;
responsive to a determination that the LBA is tagged in the eviction category, determine whether the LBA exists in the LEC list; and
responsive to a determination that the LBA does not exist in the LEC list, insert the LBA into the head end of the LEC list.

### Example 16

The apparatus of any one of Examples 13-15, wherein the processor is configured to further execute the executable instructions to set a hot flag for the LBA to indicate that the LBA has been written to the PCM media during a cycle of the LEC list in response to a determination that the LBA exists in the LEC list.

### Example 17

The apparatus of any one of Examples 13-16, wherein the processor is configured to further execute the executable instructions to:

perform a hot flag determination to determine whether the tail end LBA has the hot flag set prior to evicting the tail end LBA in response to a determination that data needs to be evicted from the PCM media;

move the tail end LBA that has the hot flag set to the head end of the LEC list and reset the hot flag in response to a determination that the tail end LBA has the hot flag set;

determine whether there are subsequent LBAs on the LEC list at the tail end with continuing write sequence number to that of the tail end LBA;

move all the subsequent LBAs on the LEC list with continuing write sequence number to that of the tail end LBA along with the tail end LBA to the head end of the LEC list and repeat the hot flag determination on a new LBA at the tail end of the LEC list in response to a determination that there are subsequent LBAs on the LEC list with continuing write sequence number to that of the tail end LBA; and
evict the tail end LBA and all the subsequent LBAs on the LEC list with continuing write sequence number to that of the tail end LBA in response to the determination that the tail end LBA does not have the hot flag set.

### Example 18

The apparatus of any one of Examples 13-17, wherein setting the hot flag comprises incrementing a counter value by one for each time the LBA is written to the PCM media, and wherein resetting the hot flag comprises decrementing the counter value by one, and wherein the hot flag is determined to be set if the counter value is greater than an initial value of the counter value.

### Example 19

The apparatus of any one of Examples 13-18, wherein the counter value has a predetermined max value, wherein additional writes of the LBA does not increase the counter value beyond the max value.

### Example 20

The apparatus of any one of Examples 13-19, wherein the processor is configured to further execute the executable instructions to store the LEC list in the PCM media using small memory units (SMUs) that are protected by error-correcting codes designed to protect against random errors, and wherein the LEC list is organized into segments, each segment stored in an SMU in random order in the PCM media, and wherein the segment contains an address linking to the next ordered segment in the list.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, while the above embodiments are described for a write cache, the disclosed embodiments may be extended to a read or a prefetch cache.

In addition, the various elements or components may be combined or integrated in another system or certain features may be omitted, or not implemented. Additionally, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein. Therefore, the specification and drawings are to be regarded simply as an illustration of the disclosure as defined by the appended claims, and are contemplated to cover any and all modifications, variations, combinations or equivalents that fall within the scope of the present disclosure.

1. A method for writing and evicting data in a phase-change memory (PCM) media, the method comprising:
storing a logical block address (LBA) eviction candidate (LEC) list in the PCM media, wherein the LEC list employs a circular queue having a head end and a tail end, wherein new LBAs are inserted at the head end;
responsive to a determination that data needs to be evicted from the PCM media, evicting a tail end LBA at the tail end of the LEC list;
determining if there are subsequent LBAs on the LEC list with continuing write sequence number to that of the tail end LBA; and
responsive to a determination that there are subsequent LBAs on the LEC list with continuing write sequence number to that of the tail end LBA, evicting all the subsequent LBAs on the LEC list with continuing write sequence number to that of the tail end LBA along with the tail end LBA.

2. method of claim 1, wherein the head end and the tail end of the LEC list is cached in static random access memory (SRAM) for quick access.

3. The method of claim 1, further comprising:
writing an LBA to the PCM media;
determining whether the LBA is tagged in an eviction category;
responsive to a determination that the LBA is tagged in the eviction category, determining whether the LBA exists in the LEC list; and
responsive to a determination that the LBA does not exist in the LEC list, inserting the LBA into the head end of the LEC list.

4. The method of claim 3, further comprising responsive to a determination that the LBA exists in the LEC list, setting a hot flag for the LBA to indicate that the LBA has been written to the PCM media during a cycle of the LEC list.

5. The method of claim 4, further comprising:
responsive to the determination that data needs to be evicted from the PCM media, prior to evicting the tail end LBA, performing a hot flag determination to determine whether the tail end LBA has the hot flag set;
responsive to the determination that the tail end LBA has the hot flag set, moving the tail end LBA that has the hot flag set to the head end of the LEC list and resetting the hot flag;
determining if there are subsequent LBAs on the LEC list at the tail end with continuing write sequence number to that of the tail end LBA;
responsive to a determination that there are subsequent LBAs on the LEC list with continuing write sequence number to that of the tail end LBA, moving all the subsequent LBAs on the LEC list with continuing write sequence number to that of the tail end LBA along with the tail end LBA to the head end of the LEC list, and repeating the hot flag determination on a new LBA at the tail end of the LEC list; and
responsive to the determination that the tail end LBA does not have the hot flag set, evicting the tail end LBA and all the subsequent LBAs on the LEC list with continuing write sequence number to that of the tail end LBA.

6. The method of claim 5, wherein setting the hot flag comprises incrementing a counter value by one for each time the LBA is written to the PCM media, and wherein resetting the hot flag comprises decrementing the counter value by one, and wherein the hot flag is determined to be set if the counter value is greater than an initial value of the counter value.

7. The method of claim 6, wherein the counter value has a predetermined max value, wherein additional writes of the LBA do not increase the counter value beyond the predetermined max value.

8. The method of claim 1, wherein the LEC list is stored in the PCM media using small memory units (SMUs) that are protected by error-correcting codes designed to protect against random errors, and wherein the LEC list is organized into segments, each segment stored in an SMU.

9. The method of claim 8, wherein the segments are stored in random order anywhere in the PCM media.

10. The method of claim 9, wherein the segment contains an address linking to a next ordered segment in the LEC list.

11. The method of claim 8, wherein each segment is 50 bytes long comprising fourteen 28-bit entries and one 8-bit increment field, the one 8-bit increment field indicating the address linking to the next ordered segment in the LEC list.

12. The method of claim 11, wherein each entry comprises a 27 bit LBA and one reserve bit.

13. An apparatus comprising:
a memory for storing executable instructions; and
a processor configured to execute the executable instructions to:
store a logical block address (LBA) eviction candidate (LEC) list in a phase-change memory (PCM) media, wherein the LEC list employs a circular queue having a head end and a tail end, wherein new LBAs are inserted at the head end;
responsive to a determination that data needs to be evicted from the PCM media, evict a tail end LBA at the tail end of the LEC list;
determine if there are subsequent LBAs on the LEC list with continuing write sequence number to that of the tail end LBA; and
responsive to a determination that there are subsequent LBAs on the LEC list with continuing write sequence number to that of the tail end LBA, evict all the subsequent LBAs on the LEC list with continuing write sequence number to that of the tail end LBA along with the tail end LBA.

14. The apparatus of claim 13, wherein the processor is configured to further execute the executable instructions to cache the head end and the tail end of the LEC list in static random access memory (SRAM) for quick access.

15. The apparatus of claim 13, wherein the processor is configured to further execute the executable instructions to:
write an LBA to the PCM media;
determine whether the LBA is tagged in an eviction category;
responsive to a determination that the LBA is tagged in the eviction category, determine whether the LBA exists in the LEC list; and
responsive to a determination that the LBA does not exist in the LEC list, insert the LBA into the head end of the LEC list.

16. The apparatus of claim 15, wherein the processor is configured to further execute the executable instructions to set a hot flag for the LBA to indicate that the LBA has been written to the PCM media during a cycle of the LEC list in response to a determination that the LBA exists in the LEC list.

17. The apparatus of claim 16, wherein the processor is configured to further execute the executable instructions to:
perform a hot flag determination to determine whether the tail end LBA has the hot flag set prior to evicting the tail end LBA in response to a determination that data needs to be evicted from the PCM media;
move the tail end LBA that has the hot flag set to the head end of the LEC list and reset the hot flag in response to a determination that the tail end LBA has the hot flag set;
determine whether there are subsequent LBAs on the LEC list at the tail end with continuing write sequence number to that of the tail end LBA;
move all the subsequent LBAs on the LEC list with continuing write sequence number to that of the tail end LBA along with the tail end LBA to the head end of the LEC list and repeat the hot flag determination on a new LBA at the tail end of the LEC list in response to a determination that there are subsequent LBAs on the LEC list with continuing write sequence number to that of the tail end LBA; and
evict the tail end LBA and all the subsequent LBAs on the LEC list with continuing write sequence number to that of the tail end LBA in response to the determination that the tail end LBA does not have the hot flag set.

18. The apparatus of claim 17, wherein setting the hot flag comprises incrementing a counter value by one for each time the LBA is written to the PCM media, and wherein resetting the hot flag comprises decrementing the counter value by one, and wherein the hot flag is determined to be set if the counter value is greater than an initial value of the counter value.

19. The apparatus of claim 18, wherein the counter value has a predetermined max value, wherein additional writes of the LBA does not increase the counter value beyond the predetermined max value.

20. The apparatus of claim 13, wherein the processor is configured to further execute the executable instructions to store the LEC list in the PCM media using small memory units (SMUs) that are protected by error-correcting codes designed to protect against random errors, and wherein the LEC list is organized into segments, each segment stored in an SMU in random order in the PCM media, and wherein the segment contains an address linking to a next ordered segment in the list.
